(19) United States
(12) Patent Application Publication
(10) Pub. No.: US 2016/0358909 A1
(43) Pub. Date: Dec. 8, 2016

(54) SYSTEMS AND METHODS FOR INCREASING PACKING DENSITY IN A SEMICONDUCTOR CELL ARRAY

(71) Applicant: Marvell World Trade Ltd., St. Michael (BB)

(72) Inventors: Sehat Sutardja, Los Altos Hills, CA (US); Winston Lee, Palo Alto, CA (US); Peter Lee, Pleasanton, CA (US); Runzi Chang, San Jose, CA (US)

(21) Appl. No.: 15/171,311

(22) Filed: Jun. 2, 2016

Related U.S. Application Data
(60) Provisional application No. 62/170,931, filed on Jun. 4, 2015.

(51) Int. Cl. H01L 27/088; H01L 29/45; H01L 29/16; H01L 29/08; H01L 29/06; H01L 21/8234

(52) U.S. Cl. CPC H01L 27/088; H01L 29/0649; H01L 21/823481; H01L 21/823418; H01L 21/823475; H01L 29/16; H01L 29/0847; H01L 29/456

(57) ABSTRACT

Systems and methods are provided for using and manufacturing a semiconductor device. A semiconductor device comprises an array of transistors, wherein each respective transistor in at least some of the transistors in the array of transistors (1) is positioned adjacent to a respective first neighboring transistor and a respective second neighboring transistor in the array of transistors, (2) has a source region that shares a first contact with a source region of the respective first neighboring transistor, and (3) has a drain region that shares a second contact with a drain region of the respective second neighboring transistor.

### CROSS REFERENCE TO RELATED APPLICATIONS

This disclosure claims the benefit under 35 U.S.C. §119(e) of U.S. Provisional Application No. 62/170,931, filed on Jun. 4, 2015, which is incorporated herein by reference in its entirety.

### FIELD OF USE

This disclosure relates generally to providing isolation between devices in a semiconductor cell array, and more particularly to increasing packing density in a transistor array.

### BACKGROUND

Transistor arrays include multiple transistors that share the same substrate and are commonly used in applications such as function generation and amplification. Existing semiconductor cell arrays are often restricted to have relatively large sizes because of a required minimum spacing between adjacent devices. This minimum spacing causes the footprint of each device cell to be relatively large, which in turn causes the overall array to have a large size.

It is generally desirable to reduce electrical leakage between adjacent devices in an array. One way to reduce or prevent current leakage between adjacent transistors is to use local oxidation of silicon (LOCOS). In a LOCOS process, certain regions surrounding the transistors are subjected to thermal oxidation, creating silicon oxide insulating structures that are immersed within and below the surface of a silicon wafer. One disadvantage of LOCOS is that the silicon oxide insulating structures are relatively large, such that a relatively small number of transistors may be formed on a single wafer. Another way to prevent current leakage between adjacent transistors is to use shallow trench isolation (STI) during the fabrication of the device. During an STI process, a pattern of trenches is etched in the silicon, and dielectric material is deposited into the trenches before the excess dielectric material is removed.

### SUMMARY

In view of the foregoing, systems and methods are provided for using and manufacturing a semiconductor device.

According to one aspect of the disclosure, a semiconductor device comprises an array of transistors, wherein each respective transistor in at least some of the transistors in the array of transistors (1) is positioned adjacent to a respective first neighboring transistor and a respective second neighboring transistor in the array of transistors, (2) has a source region that shares a first contact with a source region of the respective first neighboring transistor, and (3) has a drain region that shares a second contact with a drain region of the respective second neighboring transistor.

In some implementations, the array of transistors is a two-dimensional array, and the transistors in the array of transistors are arranged in a plurality of rows and a plurality of columns. In an example, the respective transistor and the respective first neighboring transistor share a same row, and the respective transistors and the respective second neighboring transistor share a same column. In an example, the respective transistor and the respective first neighboring transistor share the same column, and the respective transistors and the respective second neighboring transistor share the same row.

In some implementations, the first contact and the second contact of each respective transistor are rectangularly shaped.

In some implementations, a first dimension of each of the first and second contacts is between 30 and 50 nm, and a second dimension of each of the first and second contacts is between 30 and 130 nm.

In some implementations, the semiconductor device further comprises a plurality of shallow trenches, wherein each shallow trench in the plurality of shallow trenches is positioned between one of the respective transistors and the respective first neighboring transistor, and provides isolation between the one of the respective transistors and the respective first neighboring transistor. At least some of the shallow trenches may be buried underneath a layer of silicon.

In some implementations, the semiconductor device further comprises a plurality of air gaps, wherein each air gap in the plurality of air gaps is positioned between one of the respective transistors and the respective first neighboring transistor, and provides isolation between the one of the respective transistors and the respective first neighboring transistor. Each of the plurality of air gaps may be buried underneath a layer of silicon.

In some implementations, the sharing of the first contact between both source regions and the sharing of the second contact between both drain regions allows the transistors in the array of transistors to be positioned closer to one another than if the first contact and the second contact were not shared.

According to one aspect of the disclosure, a method of manufacturing a semiconductor device is described. The method comprises forming an array of transistors, wherein each respective transistor in at least some of the transistors in the array of transistors is positioned adjacent to a respective first neighboring transistor and a respective second neighboring transistor in the array of transistors. The method further comprises causing a source region of the respective transistor to share a first contact with a source region of the respective first neighboring transistor, and causing a drain region of the respective transistor to share a second contact with a drain region of the respective second neighboring transistor.

In some implementations, the array of transistors is a two-dimensional array, and the transistors in the array of transistors are arranged in a plurality of rows and a plurality of columns. In an example, the respective transistor and the respective first neighboring transistor share a same row, and the respective transistors and the respective second neighboring transistor share a same column. In an example, the respective transistor and the respective first neighboring transistor share the same column, and the respective transistors and the respective second neighboring transistor share the same row.

In some implementations, the first contact and the second contact of each respective transistor are rectangularly shaped.

In some implementations, a first dimension of each of the first and second contacts is between 30 and 50 nm, and a second dimension of each of the first and second contacts is between 30 and 130 nm.

In some implementations, the method further comprises forming a plurality of shallow trenches, wherein each shallow trench in the plurality of shallow trenches is positioned between one of the respective transistors and the respective first neighboring transistor, and provides isolation between the one of the respective transistors and the respective first neighboring transistor. The method may further comprise burying at least some of the shallow trenches underneath a layer of silicon.

In some implementations, the method further comprises forming a plurality of air gaps, wherein each air gap in the plurality of air gaps is positioned between one of the respective transistors and the respective first neighboring transistor, and provides isolation between the one of the respective transistors and the respective first neighboring transistor. The method may further comprise burying each of the plurality of air gaps underneath a layer of silicon.

In some implementations, the sharing of the first contact between both source regions and the sharing of the second contact between both drain regions allows the transistors in the array of transistors to be positioned closer to one another than if the first contact and the second contact were not shared.

### BRIEF DESCRIPTION OF THE DRAWINGS

The above and other features of the present disclosure, including its nature and its various advantages, will be more apparent upon consideration of the following detailed description, taken in conjunction with the accompanying drawings in which:

FIG. 1 is a diagram of an illustrative device cells, in accordance with an embodiment of the present disclosure;

FIG. 2 is a block diagram of an illustrative prior art cell array;

FIG. 3 is a block diagram of an illustrative cell array with increased density, in accordance with an embodiment of the present disclosure;

FIG. 4 is a block diagram of an illustrative cell array with increased density that uses shallow trench isolation, in accordance with an embodiment of the present disclosure;

FIG. 5 is a series of five diagrams that illustrate steps of a process that forms a buried STI trench, in accordance with an embodiment of the present disclosure;

FIG. 6 is a series of five diagrams that illustrate steps of a process that forms a buried air gap, in accordance with an embodiment of the present disclosure; and

FIG. 7 is a flowchart of an illustrative process for manufacturing an array of device cells, in accordance with an embodiment of the present disclosure.

### DETAILED DESCRIPTION

This disclosure generally relates to increasing packing density in a semiconductor cell array, as well as improving isolation of transistors. To provide an overall understanding of the disclosure, certain illustrative embodiments will now be described, including a transistor array that includes neighboring transistors that share contacts. However, it will be understood by one of ordinary skill in the art that the systems and methods described herein may be adapted and modified as is appropriate for the application being addressed, and that the systems and methods described herein may be employed in other suitable applications, and that such other additions and modifications will not depart from the scope thereof. For example, the embodiments herein are mostly described in relation to transistor arrays, but one of ordinary skill in the art will understand that the present disclosure may be used in any programmable logic device, field programmable gate array (FPGA), or semiconductor cell array.

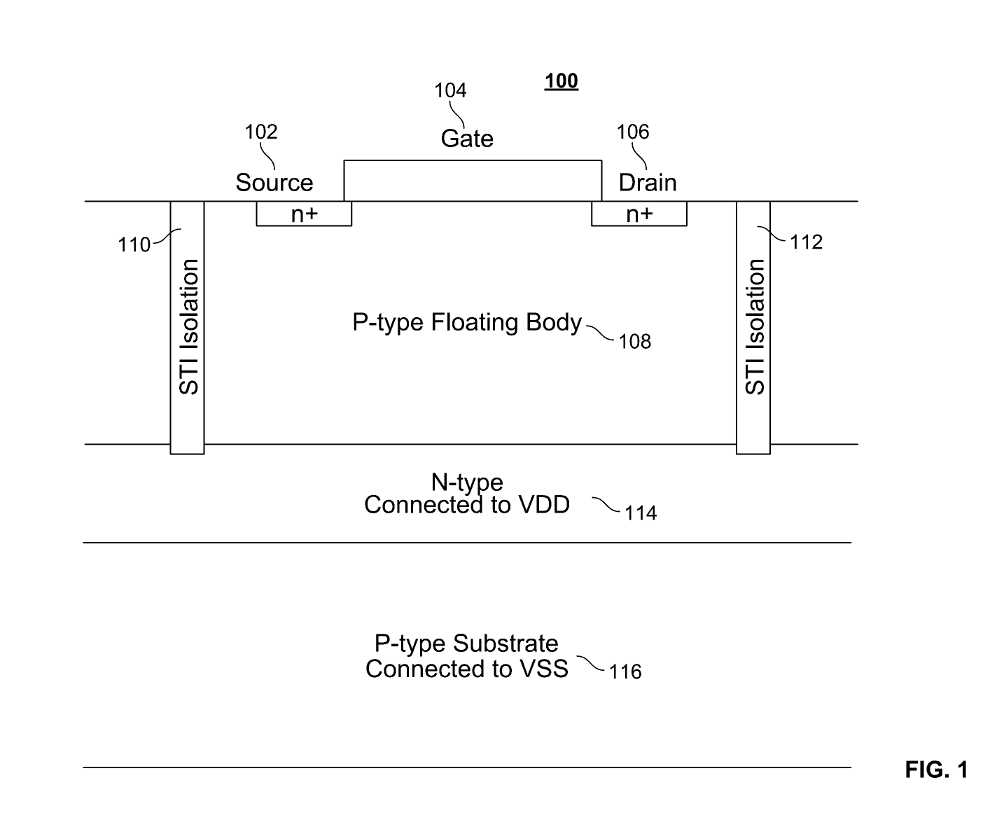

FIG. 1 shows an illustrative device body 100, in accordance with some embodiments of the present disclosure. The device body 100 is an NMOS transistor that includes an n-type source 102, a p-type gate 104, and an n-type drain 106 at its surface. The device body 100 also includes three layers, including a p-type floating body 108, an n-type region connected to VDD 114, and a p-type substrate connected to VSS 116. While only one NMOS transistor is shown in FIG. 1, there may be multiple transistors dispersed along the same row, using the same p-type floating body 108, n-type region 114, and p-type substrate 116. For example, the NMOS transistor shown in FIG. 1 may be flanked on its left and right sides by additional NMOS transistors. When transistors are positioned closely to one another in an array, electrical current may leak between transistors, which may limit performance of the transistor array.

One way to reduce or prevent current leakage between adjacent transistors is to use local oxidation of silicon (LOCOS). In a LOCOS process, certain regions surrounding the transistors are subjected to thermal oxidation, creating silicon oxide insulating structures that are immersed within and below the surface of a silicon wafer. One disadvantage of LOCOS is that the silicon oxide insulating structures are relatively large, such that a relatively small number of transistors may be formed on a single wafer. Another way to prevent current leakage between adjacent transistors is to use shallow trench isolation (STI) during the fabrication of the device. During an STI process, a pattern of trenches is etched in the silicon, and dielectric material is deposited into the trenches before the excess dielectric material is removed. Unlike LOCOS, STI may be used to increase the packing density of the transistors. As is shown in FIG. 1, two STI trenches 110 and 112 are shown that flank either side of the device body 100. Importantly, each trench 110 and 112 extends through the depth of the p-type floating body 108 and partially into the n-type region 114.

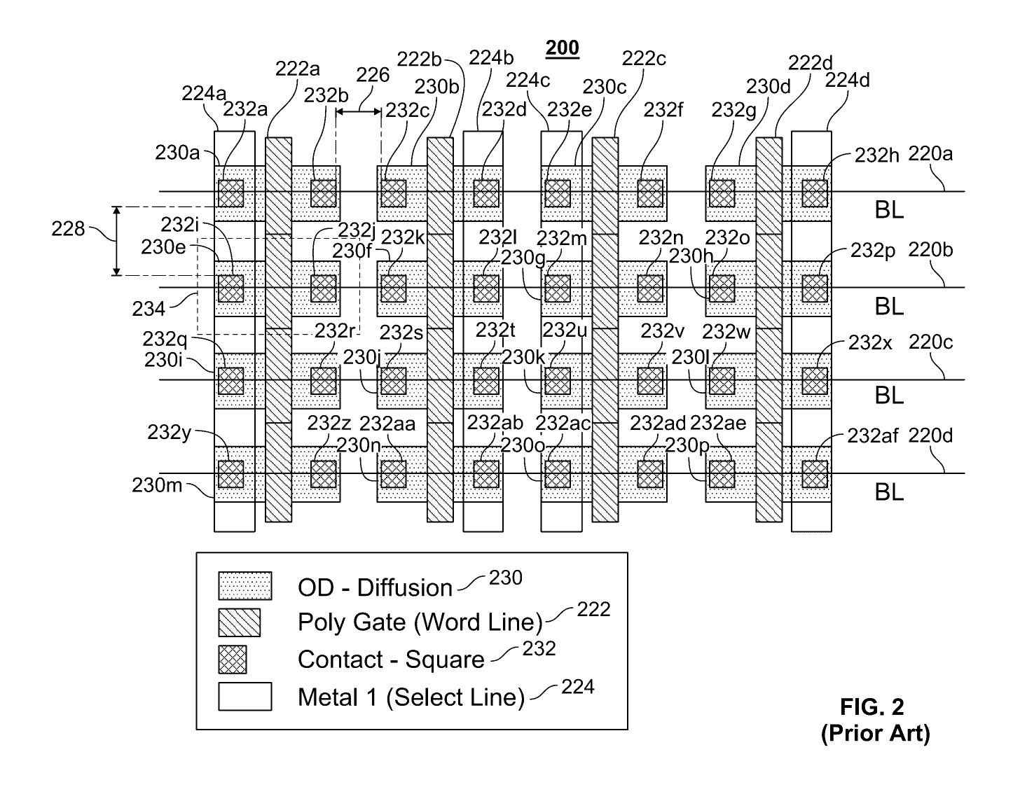

FIG. 2 shows an illustrative top view of a prior art cell array 200. The cell array 200 includes sixteen device cells 234 arranged in a two-dimensional 4×4 array. Each device cell corresponds to a transistor having three terminals: drain, source, and gate. Four vertical word lines 222a-222d (generally, word line 222) pass through the gates of the device cells. Four vertical select lines 224a-224d (generally, select line 224) pass through the drains or sources of the device cells. Four horizontal bit lines 220a-220d (generally, bit line 220) pass through each row of four device cells. Each drain and gate terminal on each of the device cells has a corresponding square contact 232a-232af (generally, square contact 232) that is specific to each individual terminal and is positioned fully within the boundaries of the diffusion regions 230a-230p (generally, diffusion region 230) of each device cell.

In the cell array 200, the bit lines 220 are positioned far apart from one another to accommodate the large diffusion regions 230 of each device and to prevent devices from leaking electrical current to their neighboring devices. In particular, the size of each device and the minimum spacing between each device is limited by the required vertical contact-to-contact spacing 228 and the required horizontal contact-to-contact spacing 226. For example, when the size of each square contact 232 is 40 nm×40 nm, the required spacings 228 and 226 may be approximately 90 nm or between 80 to 100 nm. In general, the contact-to-contact spacing in the prior art cell array 200 must be relatively large because it has been traditionally difficult to manufacture small contacts 232. To create the contacts 232, photolithography is used to transfer a geometric pattern from a photomask to a light-sensitive chemical photoresist on a substrate. The geometric pattern includes tiny holes that are used to eventually form the contacts 232. Because the holes are so small, it is difficult for light to pass through the pattern without interfering with other holes. Accordingly, the spacing between the holes must be relatively large to ensure non-interference between adjacent holes. This spacing between holes in the geometric pattern results in a required minimum spacing between the contacts 232. Accordingly, photolithography limits the size and the spacing of the square contacts 232, causing the footprint of each device cell to be relatively large in both dimensions (vertical and horizontal as shown in FIG. 2.

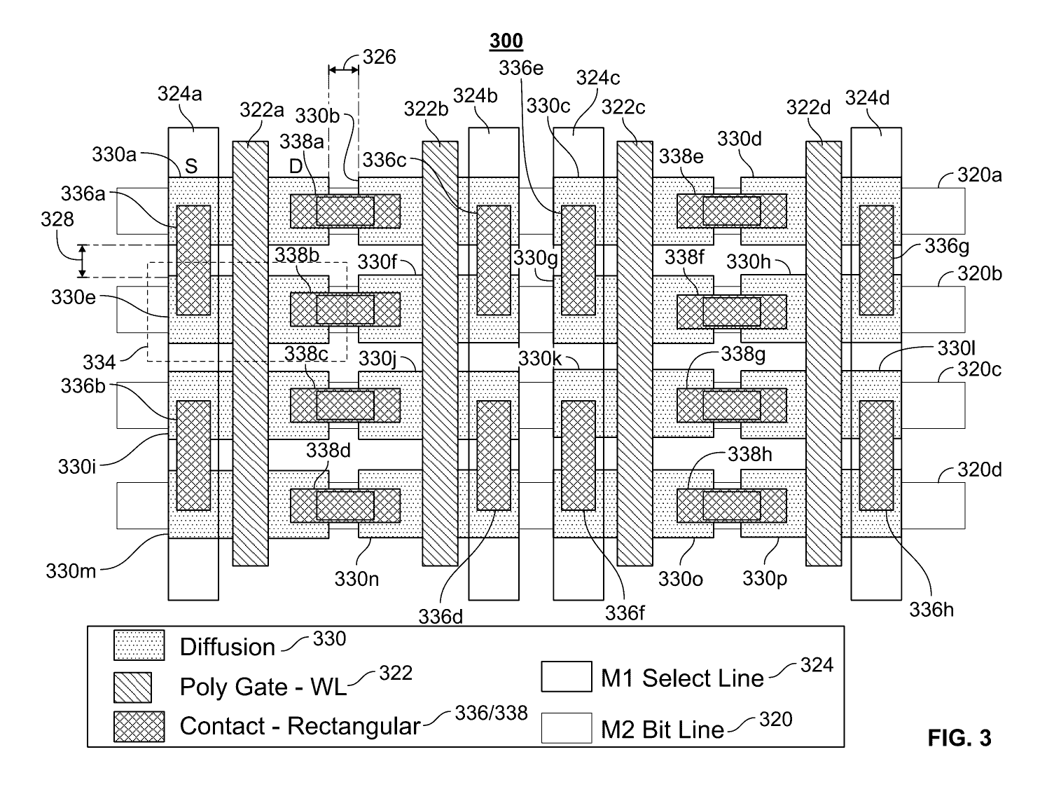

The systems and methods of the present disclosure reduce the foot print of each cell by allowing neighboring device cells to share one or more contacts. Rather than requiring that each contact be restricted to a single device cell, allowing two neighboring device cells to share a single contact means that the device cells can be positioned a lot closer to one another than is shown in FIG. 2. An example of a cell array where neighboring device cells share a contact is shown and described in relation to FIG. 3.

FIG. 3 shows an illustrative top view of a cell array 300, in accordance with some embodiments of the present disclosure. The cell array 300 includes sixteen device cells 334 arranged in a two-dimensional 4×4 array. Within the cell array 300, four vertical word lines 322a-322d (generally, word line 322) pass through the gates of the device cells, four vertical M1 select lines 324a-324d (generally, M1 select line 324) pass through the drains or sources of the device cells, and four horizontal M2 bit lines 320a-320d (generally, M2 bit line 320) pass through each row of four device cells. Each drain and source terminal on each of the device cells 334 has a corresponding vertical rectangular contact 336a-336h (generally, vertical rectangular contact 336) or a corresponding horizontal rectangular contact 338a-338h (generally, horizontal rectangular contact 338). In contrast to the square contacts 232 of FIG. 2, each rectangular contact 336 and 338 spans over two different neighboring device cells 334. The rectangular contacts 336 and 338 may be larger than the square contacts 232, such that the rectangular contacts 336 and 338 are easier to manufacture using photolithography and are associated with better manufacturing fidelity than the square contacts 232.

Each vertical contact 336 extends into two M2 bit lines and across the source regions of two device cells that are positioned vertically from each other. In particular, a top row of four vertical contacts (336a, 336c, 336e, and 336g) extend over the M2 bit lines 320a and 320b (and the source regions of the corresponding device cells), and a second row of four vertical contacts (336b, 336d, 336f, and 336h) extend over the M2 bit lines 320c and 320d (and the source regions of the corresponding device cells). Similarly, each horizontal contact 338 extends across the drain regions of two device cells that are positioned horizontally from each other. In particular, a first column of four horizontal contacts (338a, 338b, 338c, and 338d) extend between the drain regions of the leftmost two columns of device cells, and a second column of four horizontal contacts (338e, 338f, 338g, and 338h) extend between the drain regions of the rightmost two columns of device cells. Each horizontal rectangular contact 338 is connected to an M1 select line 324. As is shown in FIG. 3, the vertical contacts 336 extend across the source regions and the horizontal contacts extend across the drain regions. One of ordinary skill in the art will understand that the vertical contacts 336 may extend across drain regions and the horizontal contacts 338 may extend across the source regions of the cell array 300, without departing from the scope of the present disclosure. Moreover, the vertical contacts 336 may extend across the source regions and the horizontal contacts may extend across the drain regions in certain areas of a cell array, while other vertical contacts 336 may extend across the drain regions and other horizontal contacts may extend across the source regions in other areas of the same cell array.

In the prior art cell array 200 shown in FIG. 2, the contact-to-contact spacing had a minimum value that restricted the size of each device and the spacing between the devices to be relatively large. In other words, to ensure that no interference occurred between contacts, the spacing between contacts was required to be large in the prior art cell array 200. In contrast, the configuration of the cell array 300 shown in FIG. 3 allows a device cell to share one contact within its source region with a first neighboring device cell, and to share another contact within its drain region with a second neighboring device cell. In the prior art cell array 200, the minimum cell size and spacing was limited by the required contact-to-contact spacing. In the cell array 300 of the present disclosure, the required contact-to-contact spacing restriction is removed, such that the device cells may be packed much more densely.

In the cell array 300, two neighboring diffusion regions are shown as sharing a contact. Accordingly, for the cell array 300, the diffusion-to-diffusion spacing is the limiting factor that restricts the size and spacing of each device. Compared to contact-to-contact spacing, diffusion-to-diffusion spacing is a much more relaxed rule, which means that the devices in the cell array 300 are much smaller in size and are positioned much more closely together than the devices in the prior art cell array 200. In particular, the size of each device and the minimum spacing between each device is limited by the required vertical diffusion-to-diffusion spacing 328 (which is much smaller than the contact-to-contact spacing 228 of FIG. 2) and the required horizontal diffusion-to-diffusion spacing 326 (which may be approximately 40 nm or between 30 to 50 nm, and is much smaller than the contact-to-contact spacing 226 of FIG. 2 of approximately 90 nm). A smaller device cell size and smaller spacing between devices means that more devices can occupy the same amount of area, and translates into a significantly more efficient device. While two diffusion regions are shown in FIG. 3 as sharing a contact, one of ordinary skill in the art will understand that in general, a device cell array may include more than two diffusion regions sharing a single contact, such as 3, 4, 5, or any suitable number of diffusion regions, without departing from the scope of the present disclosure.

Compared to the prior art cell array 200, the bit lines 320 of the cell array 300 are spaced much more closely together than the bit lines 220, due to the use of the vertical rectangular contacts 336. However, the cell array 300 has reduced flexibility compared to the prior art cell array 200, because each individual device cell in the prior art cell array 200 is configured to operate independently from one another, while each device cell in the cell array 300 is forced to share its contacts with its neighbors. Nonetheless, the drastic improvement in packing density in the cell array 300 greatly outweighs the disadvantages of having reduced flexibility. For example, when the cell array 300 is used in a random logic circuit, the device cells are used as a group of memory cells. In this case, the circuit's flexibility is less important than the packing density because it is more desirable to have a smaller chip that has large memory storage capacity than to have each device cell able to operate independently from one another.

In some implementations, a size of the square contact 232 of the prior art cell array 200 is 40 nm×40 nm, causing the contact-to-contact spacing to be roughly 90 nm. In some implementations, a size of the rectangular contacts 336 and 338 is 40 nm×130 nm. In this case, the spacing between the contacts may be the same as in the prior art cell array 200, but the larger contact is associated with a better manufacturing process window. The better manufacturing process window ensures fidelity of the repeatability of manufacturing the larger rectangular contact, compared to the smaller square contact. Moreover, the larger size of the rectangular contact means that more conducting material is used to create the contact. This corresponds to a lower contact resistance than the square contacts 232 in the prior art cell array, which improves the performance of the cell array 300.

Even though using rectangular contacts with the size 40 nm×130 nm improves the manufacturing process window of the cell array, this size does not improve the packing density compared to the prior art cell array 200 with square contacts having the size 40 nm×40 nm. Furthermore, the use of rectangular contacts that overlap over two devices in the cell array reduces the flexibility of the circuit. In some implementations, the size of the rectangular contacts 336 and 338 may be reduced to improve the packing density of the cell array. Example sizes of such rectangular contacts 336 and 338 may include 40 nm×100 nm, 40 nm×80 nm, or any other suitable size.

In general, the tradeoff between circuit flexibility and the packing density of a cell array may be used to design a cell array to meet the requirements of a particular device. In one example, the small square contacts 232 of FIG. 2 may be used to replace the vertical rectangular contacts 336 in FIG. 3, while the horizontal rectangular contacts 338 are still used. In this case, there is no improvement in packing density in the vertical direction, but packing density is improved in the horizontal direction. In another example, the small square contacts 232 of FIG. 2 may be used to replace the horizontal rectangular contacts 338 in FIG. 3, while the vertical rectangular contacts 336 are still used. In this case, there is no improvement in packing density in the horizontal direction, but packing density is improved in the vertical direction. In both of these examples, the packing density is improved in only one direction but is not improved in the other direction. For optimal packing density, rectangular contacts would be used in both directions. However, such a configuration may be useful if it is desirable to maintain some flexibility in the circuit such that some device cells have at least one contact that is independent from any other device cell.

In some implementations, dummy device cells are positioned on parts or all of the edges of the cell array 300. In particular because the rectangular contacts 336 and 338 extend over two device cells, if a rectangular contact is printed at the edge of the device, the rectangular contact may extend over only one device cell. The dummy device cells may be used at the edges of the cell array for ease of manufacturability.

As is shown in FIG. 3, the contacts 336 and 338 are shaped as rectangular. However, one of ordinary skill in the art will understand that in general, the contacts 336 and/or the contacts 338 may be rectangular-shaped or square-shaped, without departing from the scope of the present disclosure. For example, the contacts 336 and/or the contacts 338 may be square-shaped and overlap over two neighboring device cells. As another example, the contacts 336 and/or the contacts 338 may be rectangular-shaped and do not overlap over any two neighboring device cells. However, for the highest packing density, both the contacts 336 and the contacts 338 will overlap over at least two neighboring device cells, regardless of their shape.

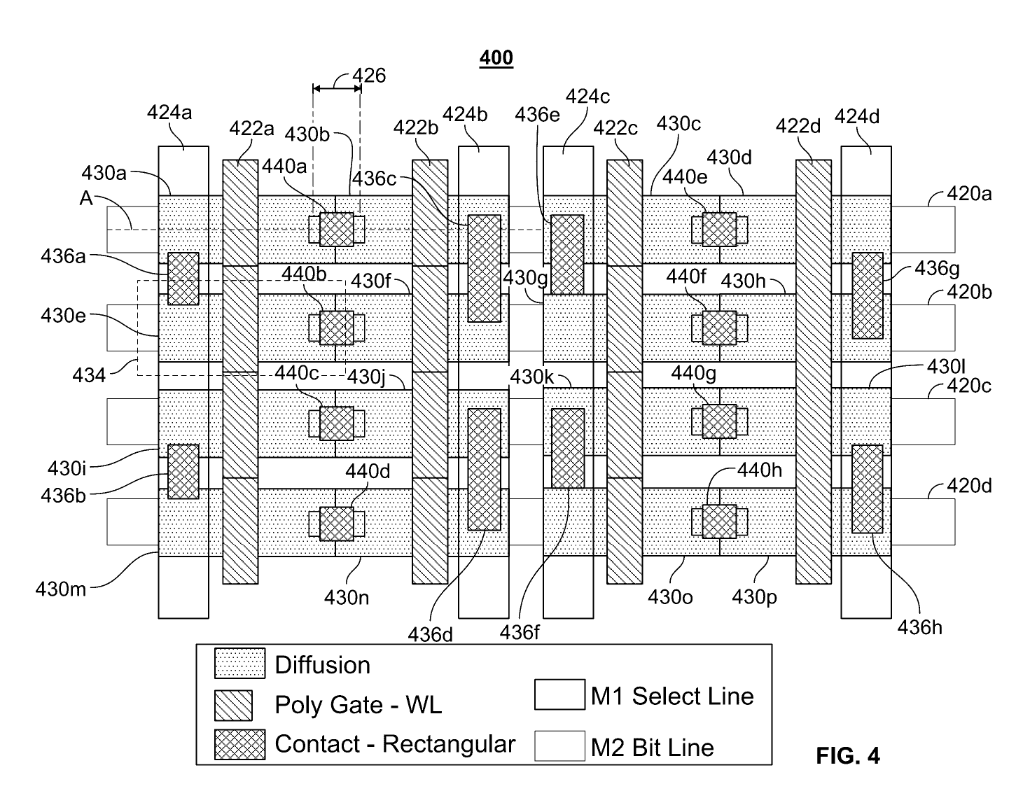

FIG. 4 shows an illustrative top view of a cell array 400, in accordance with some embodiments of the present disclosure. The cell array 400 is similar to the cell array 300 shown in FIG. 3, except that the device cells 444 in the cell array 400 are positioned even closer to one another than the device cells in FIG. 3. The cell array 400 includes sixteen device cells 434 arranged in a two-dimensional 4×4 array. Within the cell array 400, four vertical word lines 422a-422d (generally, word line 422) pass through the gates of the device cells, four vertical M1 select lines 424a-424d (generally, M1 select line 424) pass through the drains or sources of the device cells, and four horizontal M2 bit lines 420a-420d (generally, M2 bit line 420) pass through each row of four device cells. Each drain and source terminal on each of the device cells 434 has a corresponding vertical contact 436a-436h (generally, vertical contact 436) or a corresponding horizontal contact 440a-440h (generally, horizontal contact 440). Each contact 436 and 440 spans over two different device cells 434.

In contrast to the horizontal rectangular contacts 338 shown and described in relation to FIG. 3, the horizontal contacts 440 in FIG. 4 span over two diffusion regions 430 that share an edge. This causes the vertical word lines 422 to be spaced closer to one another than the vertical word lines 322 in FIG. 3. In particular, the diffusion-to-diffusion spacing 326 between two diffusion regions 330 in FIG. 3 is removed in FIG. 4, such that the device cells 434 are positioned even closer together than the device cells in FIG. 3.

In some implementations, an STI process is used to positioned the vertical word lines 422 closer to one another in FIG. 4, as compared to the vertical word lines 322 in FIG. 3. As was described in relation to FIG. 1, an STI trench provides isolation between two adjacent devices, and may be used to reduce the spacing between the gate and an STI trench. In particular, because the contacts for the source and drain regions of the devices in the array are rectangular and/or overlap over two neighboring devices, each contact will cover both sides of the STI trench.

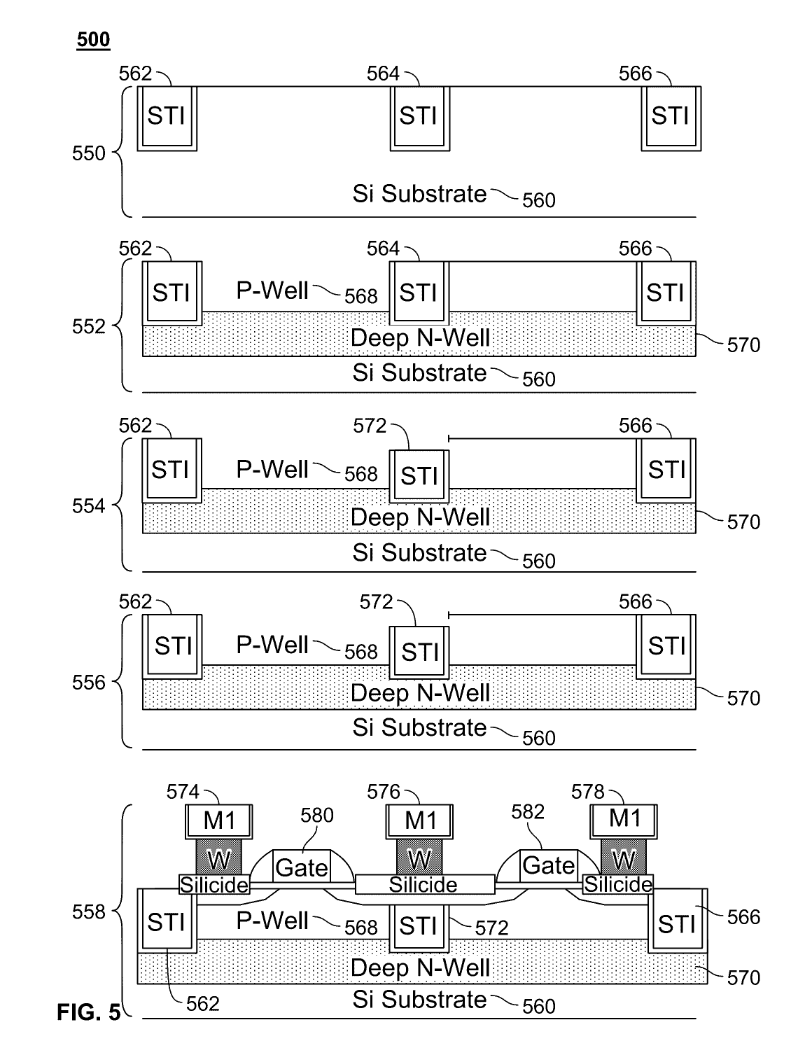

As is shown in FIG. 4, square contacts 440 (instead of rectangular contacts) may be used to extend over two neighboring device cells. Moreover, as is described in relation to FIG. 5, a buried STI trench may be formed underneath each square contact 440, below which M1 select lines are formed. As is depicted in FIG. 4, the M1 select lines 424a-424d form long vertical lines along the length of the rectangular contacts. M1 select lines also exist underneath the square contacts 440, but do not form long vertical lines. To form a buried STI trench, an example process is shown and described in relation to FIG. 5.

FIG. 5 shows an illustrative series 500 of five diagrams 550, 552, 554, 556, and 558 at five different points of a process that generates buried STI, in accordance with some embodiments of the present disclosure. Each of the diagrams 550, 552, 554, 556, and 558 illustrates a cross section of a portion of the cell array 400 shown in FIG. 4 (along the axis A) as the cell array 400 is being manufactured.

In a first step, as is shown in the first diagram 550, three shallow trenches 562, 564, and 566 are formed within a silicon substrate 560. The second diagram 552 shows a second step, during which a deep N-well 570 and a P-well 568 are implanted by doping the different layers of the silicon substrate 560. In a third step, the top portion of the shallow trench 564 is etched back to form a buried shallow trench 572, which is shown in the third diagram 554. In particular, to etch the top portion of the shallow trench 564, at least one extra mask may be used to etch the shallow trench 564 than is used for the shallow trenches 562 and 566. These shallow trenches 562 and 566 remain unburied in the third diagram 554.

In a fourth step, as is shown in the fourth diagram 556, silicon is deposited (using epitaxy or another process to grow a layer of silicon) on the buried shallow trench 572, which is then etched or polished back to create a flat surface. Finally, in a fifth step that is shown in the fifth diagram 558, the remaining processes are completed for the device, including implanting the gates 580 and 582, spacer, source/drain implants, silicide, contacts, metallization, and any other steps necessary to build the device. As is shown in the fifth diagram 558, the contacts are formed from tungsten (W) material or a material that includes tungsten as a component.

The final product shown in the fifth diagram 558 depicts the buried STI trench 572 as isolating two neighboring devices from each other. In particular, the P-well regions of the two neighboring devices must be isolated by the junction. Accordingly, the buried STI trench 572 is depicted as extending at least as deep as the bottom edge of the P-well region 568, and even extends into the deep N-well region 570. The buried STI trench 572 lays underneath the square-like contact 440a of FIG. 4, which is connected to an M1 select line 576. By burying the STI trench 572 underneath the square-like contact 440a, the two diffusion regions of two neighboring cells (diffusion regions 430a and 430b, for example) may be positioned so close to each other that they nearly touch or slightly touch or overlap. Because the neighboring cells are allowed to be positioned so closely to each other, the density of the cell array 400 is further improved.

In some implementations, the edge of the STI trench 572 (and/or the STI trench 562) is positioned very close to the edge of the gate. In this case, there is an extremely small area of left over source and drain region on the left and right sides of the contact (e.g., the region of the silicide uncovered by the contact W). The contact (indicated by W) may not touch this small area and may effectively land only on top of the buried STI trench 572. When this occurs, in order for the contact (that is positioned on top of the buried STI trench 572) to connect to source and drain area, silicon (or other semiconductor material, such as silicon germanium SiGe or indium gallium arsenide InGaAs, for example) may be deposited or grown to bridge the sources (and/or drains) of adjacent device cells.

In some implementations, as was described in relation to the diagrams 554 and 556, the surface of the STI trench 564 is etched down, and silicon or polysilicon is deposited or grown in the etched regions. This effectively creates a buried STI trench 572 so that the top surface of the device is flat and is compatible with CMOS processing steps. To keep the resistance of the contact low, a salicide process may be used to form a metal silicide contact for the source and/or drain regions, including the silicon material that is grown or deposited on top of the buried STI trench 572.

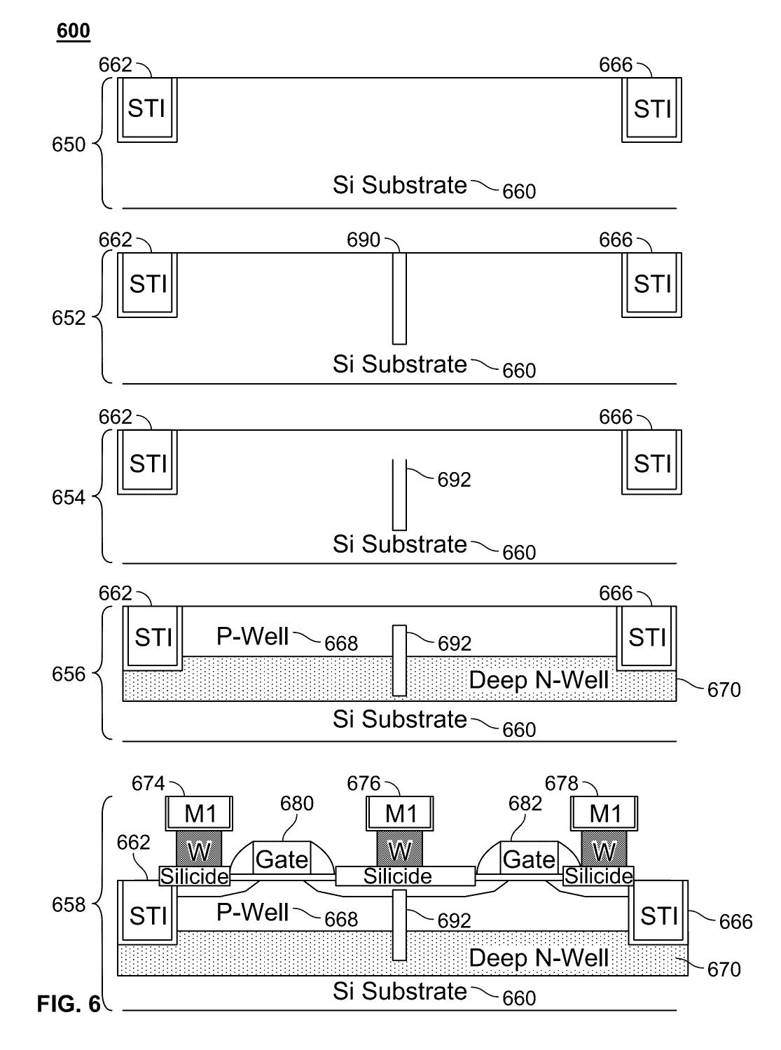

In some implementations, the silicon cavities are buried prior to normal CMOS processing steps. For example, very narrow cavities may be etched that resemble the STI trenches shown in FIG. 5. However, instead of filling the trenches with oxide, the silicon wafer may be placed in an epitaxial chamber to seal the top part of the trenches with silicon (or silicon may be deposited via a chemical vapor deposition (CVD) process). In this case, the extremely narrow cavities may be useful to build extremely small device cells and position the device cells closely together. One benefit of burying silicon cavities is that the cavity depth can be independent from the depth of the STI trench. In an example, an extremely narrow cavity may be used to replace STI 572 in FIG. 5 and is described in more detail in relation to FIG. 6. In some embodiments, two or more independent STI depths may be used. Having independent STI depths may enable extra base width tuning and therefore optimization of the bipolar characteristics of the vertical bipolar (N/P/N) device). For example, independent STI depths may include one depth for general logic and peripheries and another depth for cell arrays between pairs of cells.

FIG. 6 shows an illustrative series 600 of five diagrams 650, 652, 654, 656, and 658 at five different points of a process that generates buried STI with an air gap, in accordance with some embodiments of the present disclosure. Similarly to the series 500 shown in FIG. 5, each of the diagrams 650, 652, 654, 656, and 658 illustrates a cross section of a portion of the cell array 400 shown in FIG. 4 (along the axis A) as the cell array 400 is being manufactured.

In a first step, as is shown in the first diagram 650, two shallow trenches 662 and 666 are formed within a silicon substrate 660. The second diagram 662 shows a second step, during which at least one extra mask is used to etch a deep and narrow trench 690 within the silicon substrate 660 between the two shallow trenches 662 and 666. In a third step depicted in the third diagram 654, the top opening of the deep and narrow trench 690 is sealed by depositing silicon (using epitaxy or another process to grow a layer of silicon). The result is an air gap 692 that is surrounded on all sides by the silicon substrate 660. The buried air gap 692 is formed due to a loading effect that causes the top portion of the unburied air gap to grow silicon faster than the bottom portion of the air gap. If necessary, the top surface of the device may be etched or polished back to render a smooth top surface of the silicon substrate 660.

In a fourth step depicted in the fourth diagram 656, a deep N-well 670 and a P-well 668 are implanted by doping different layers of the silicon substrate 660. Finally, in a fifth step that is shown in the fifth diagram 658, the remaining processes are completed for the device, including implanting the gates 680 and 682, spacer, source/drain implants, silicide, contacts, metallization, and any other steps necessary to build the device.

Accordingly, the air gap 692 in the fifth diagram 658 isolates the neighboring devices from each other. By using a deep and narrow air gap in between two devices, the neighboring devices may be brought even closer to each other because the width of the air gap may be narrower than the width of an STI trench. To produce a narrower width of the air gap 692 compared to a wider width of an STI trench (such as the STI trench 662 or 666, for example), at least one extra mask may be used to etch the air gap 692. In an example, an approximate width of an STI trench may be 40 nm, or between 30 to 50 nm. The width of the air gap may range between 3 to 30 nm. In some embodiments, one or both of the STI trenches 662 and 666 may be replaced with an air gap. However, this may make the integration process more challenging. In particular, the widths of STI trenches may be more difficult to control in the logic region of the chip, and may therefore include random variations. In this case, wider trenches may not be capable of reliably forming air gaps. Furthermore, due to isolation requirements, different materials or extra masking steps may need to be employed to achieve isolation, further complicating the process.

As is shown in FIGS. 5 and 6, an array of NMOS transistors is formed. However, one of ordinary skill in the art will understand that in general, an array of PMOS transistors may be formed without departing from the scope of the present disclosure. For the NMOS transistor examples shown in FIGS. 5 and 6, the deep N-well region is isolated from the P-well regions by an STI trench or an air gap. For an example PMOS transistor array, a deep P-well region may be isolated from N-well regions by an STI trench or an air gap.

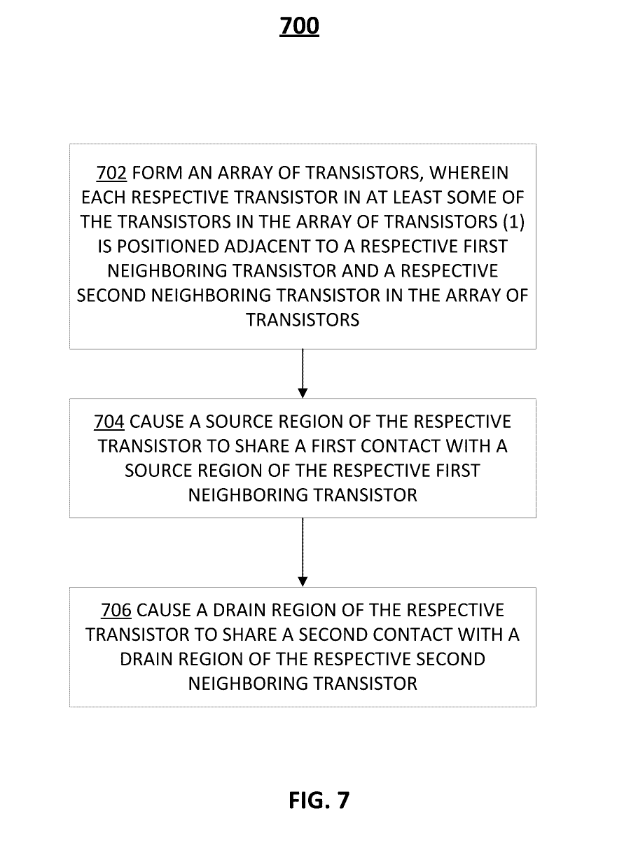

FIG. 7 shows a high level flow chart for a process 700 for manufacturing a semiconductor device, in accordance with an embodiment of the present disclosure.

At 702, an array of transistors is formed, where each respective transistor in at least some of the transistors in the array of transistors is positioned adjacent to a respective first neighboring transistor and a respective second neighboring transistor in the array of transistors. In some embodiments, the array of transistors is a two-dimensional array, and the transistors in the array of transistors are arranged in a plurality of rows and a plurality of columns, such as the cell arrays shown in FIGS. 3 and 4.

At 704, the process 700 includes causing a source region of the respective transistor to share a first contact with a source region of the respective first neighboring transistor, and at 706, the process 700 includes causing a drain region of the respective transistor to share a second contact with a drain region of the respective second neighboring transistor. In some embodiments, when the array of transistors is a two-dimensional array, the respective transistor and the respective first neighboring transistor share a same row, and the respective transistors and the respective second neighboring transistor share a same column. In other embodiments, the respective transistor and the respective first neighboring transistor share the same column, and the respective transistors and the respective second neighboring transistor share the same row.

In still other embodiments, some transistors in an array may share source contacts with neighboring transistors in the same row, while other transistors in the same array may share source contacts with neighboring transistors in the same column. Similarly, some transistors in an array may share drain contacts with neighboring transistors in the same row, while other transistors in the same array may share drain contacts with neighboring transistors in the same column.

In some embodiments, the first contact and the second contact of each respective transistor are rectangularly shaped, such as is shown and described in relation to FIG. 3. Alternatively, all of the contacts or a subset of the contacts (such as solely the drain contacts, solely the source contacts, solely the contacts that extend across the same row, solely the contacts that extend across the same column, or any suitable combination thereof) may be shaped as squares, while the remaining contacts may be rectangularly shaped. In one example, a first dimension of the first and/or second contacts may be between 30 and 50 nm or between 10 and 50 nm, while a second dimension of the first and/or second contacts may be between 30 and 130 nm or between 10 and 1000 nm.

In some embodiments, a plurality of shallow trenches are formed. Each shallow trench in the plurality of shallow trenches may be positioned between one of the respective transistors and the respective first neighboring transistor, and provide isolation between the one of the respective transistors and the respective first neighboring transistor, as is shown and described in detail in relation to the STI trenches of FIGS. 4 and 5. In particular, at least some of the shallow trenches may be buried underneath a layer of silicon.

In some embodiments, a plurality of air gaps are formed. Each air gap in the plurality of air gaps may be positioned between one of the respective transistors and the respective first neighboring transistor (and/or the respective second neighboring transistor), and provides isolation between the one of the respective transistors and the respective first neighboring transistor (and/or the respective second neighboring transistor. As is described in detail in relation to FIG. 6, at least some of the air gaps may be buried underneath a layer of silicon.

In some embodiments, the sharing of the first contact between both source regions and the sharing of the second contact between both drain regions allows the transistors in the array of transistors to be positioned closer to one another than if the first contact and the second contact were not shared. In some embodiments, only the first contact is shared between two source regions, and none of the drain contacts are shared. In some embodiments, only the second contact is shared between two drain regions, and none of the source contacts are shared. In some embodiments, only the contacts connecting two transistors in the same row are shared, and contacts along the column direction are not shared. In some embodiments, only the contacts connecting two transistors in the same column are shared, and contacts along the row direction are not shared. In any of these cases, the packing density of the cell array is improved compared to the prior art cell array depicted in FIG. 2, because at least some of the contacts are shared between neighboring devices.

While various embodiments of the present disclosure have been shown and described herein, it will be obvious to those skilled in the art that such embodiments are provided by way of example only. Numerous variations, changes, and substitutions will now occur to those skilled in the art without departing from the disclosure. It should be understood that various alternatives to the embodiments of the disclosure described herein may be employed in practicing the disclosure. It is intended that the following claims define the scope of the disclosure and that methods and structures within the scope of these claims and their equivalents be covered thereby.

What is claimed is:

1. A semiconductor device, comprising:
an array of transistors, wherein each respective transistor in at least some of the transistors in the array of transistors
(1) is positioned adjacent to a respective first neighboring transistor and a respective second neighboring transistor in the array of transistors,
(2) has a source region that shares a first contact with a source region of the respective first neighboring transistor, and
(3) has a drain region that shares a second contact with a drain region of the respective second neighboring transistor.

2. The semiconductor device of claim 1, wherein the array of transistors is a two-dimensional array, and the transistors in the array of transistors are arranged in a plurality of rows and a plurality of columns.

3. The semiconductor device of claim 2, wherein (1) the respective transistor and the respective first neighboring transistor share a same row, and the respective transistors and the respective second neighboring transistor share a same column, or (2) the respective transistor and the respective first neighboring transistor share the same column, and the respective transistors and the respective second neighboring transistor share the same row.

4. The semiconductor device of claim 1, wherein the first contact and the second contact of each respective transistor are rectangularly shaped.

5. The semiconductor device of claim 1, wherein a first dimension of each of the first and second contacts is between 30 and 50 nm, and a second dimension of each of the first and second contacts is between 30 and 130 nm.

6. The semiconductor device of claim 1, further comprising a plurality of shallow trenches, wherein each shallow trench in the plurality of shallow trenches is positioned between one of the respective transistors and the respective first neighboring transistor, and provides isolation between the one of the respective transistors and the respective first neighboring transistor.

7. The semiconductor device of claim 6, wherein at least some of the shallow trenches are buried underneath a layer of silicon.

8. The semiconductor device of claim 1, further comprising a plurality of air gaps, wherein each air gap in the plurality of air gaps is positioned between one of the respective transistors and the respective first neighboring transistor, and provides isolation between the one of the respective transistors and the respective first neighboring transistor.

9. The semiconductor device of claim 8, wherein each of the plurality of air gaps is buried underneath a layer of silicon.

10. The semiconductor device of claim 1, wherein the sharing of the first contact between both source regions and the sharing of the second contact between both drain regions allows the transistors in the array of transistors to be positioned closer to one another than if the first contact and the second contact were not shared.

11. A method of manufacturing a semiconductor device, the method comprising:
forming an array of transistors, wherein each respective transistor in at least some of the transistors in the array of transistors is positioned adjacent to a respective first neighboring transistor and a respective second neighboring transistor in the array of transistors;
causing a source region of the respective transistor to share a first contact with a source region of the respective first neighboring transistor; and
causing a drain region of the respective transistor to share a second contact with a drain region of the respective second neighboring transistor.

12. The method of claim 11, wherein the array of transistors is a two-dimensional array, and the transistors in the array of transistors are arranged in a plurality of rows and a plurality of columns.

13. The method of claim 12, wherein (1) the respective transistor and the respective first neighboring transistor share a same row, and the respective transistors and the respective second neighboring transistor share a same column, or (2) the respective transistor and the respective first neighboring transistor share the same column, and the respective transistors and the respective second neighboring transistor share the same row.

14. The method of claim 11, wherein the first contact and the second contact of each respective transistor are rectangularly shaped.

15. The method of claim 11, wherein a first dimension of each of the first and second contacts is between 30 and 50 nm, and a second dimension of each of the first and second contacts is between 30 and 130 nm.

16. The method of claim 11, further comprising forming a plurality of shallow trenches, wherein each shallow trench in the plurality of shallow trenches is positioned between one of the respective transistors and the respective first neighboring transistor, and provides isolation between the one of the respective transistors and the respective first neighboring transistor.

17. The method of claim 16, further comprising burying at least some of the shallow trenches underneath a layer of silicon.

18. The method of claim 11, further comprising forming a plurality of air gaps, wherein each air gap in the plurality of air gaps is positioned between one of the respective transistors and the respective first neighboring transistor, and provides isolation between the one of the respective transistors and the respective first neighboring transistor.

19. The method of claim 18, further comprising burying each of the plurality of air gaps underneath a layer of silicon.

20. The method of claim 11, wherein the sharing of the first contact between both source regions and the sharing of the second contact between both drain regions allows the transistors in the array of transistors to be positioned closer to one another than if the first contact and the second contact were not shared.
